(19) United States
(12) Patent Application Publication
(10) Pub. No.: US 2009/0121276 A1
(43) Pub. Date: May 14, 2009

(54) NONVOLATILE MEMORY DEVICES WITH RECESSED WORD LINES

(75) Inventors: Tea-Kwang Yu, Gyeonggi-do (KR); Jeong-Uk Han, Gyeonggi-do (KR); Yong-Tae Kim, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/267,679

(22) Filed: Nov. 10, 2008

(30) Foreign Application Priority Data
Nov. 8, 2007 (KR) 10-2007-0113795

(51) Int. Cl. H01L 29/788

(52) U.S. Cl. 257/321; 257/E29.3

(57) ABSTRACT

A nonvolatile memory device includes a substrate, a device isolation region disposed in the substrate and abutting a sidewall of an active region defined in the substrate, the device isolation region having a recessed portion and a word line crossing the active region and the recessed portion of the device isolation region and conforming to the sidewall adjacent the recessed portion of the device isolation region. The nonvolatile memory device may further include a sense line crossing the active region and the device isolation region parallel to the word line, the sense line overlying a portion of the device isolation region having a top surface at substantially the same level as a top surface of the active region. An edge of the active region adjacent the sidewall may be rounded.

### CROSS-REFERENCE TO RELATED APPLICATIONS

This U.S. non-provisional patent application claims priority under 35 U.S.C. §119 of Korean Patent Application No. 10-2007-0113795, filed on Nov. 8, 2007, the entire contents of which are hereby incorporated by reference.

### BACKGROUND OF THE INVENTION

The present invention disclosed herein relates to semiconductor memory devices and methods of manufacturing the same, and more particularly, to nonvolatile memory devices and methods of manufacturing the same.

Nonvolatile memory devices can maintain stored data while external power is turned off. Examples of nonvolatile memory devices include mask read only memory (mask ROM) devices, erasable programmable read-only memory (EPROM) devices, electrically erasable programmable read-only memory (EEPROM) devices, and flash memory devices. Flash memory devices may be classified into NOR type flash memory devices and NAND type flash memory devices.

FIG. 1 is a plan view of a conventional EEPROM device. FIGS. 2 and 3 are cross-sectional views taken along lines I-I′ and II-II′ of FIG. 1, respectively. Referring to FIGS. 1 through 3, the conventional EEPROM device includes an active region 12 defined by a device isolation regions 13 in a semiconductor substrate 11. The active region 12 includes a source region 12s, a drain region 12d, and a floating diffusion region 12f. A sense line SL crosses the active region 12. A word line WL is spaced apart from and parallel to the sense line SL.

An interlayer dielectric 30 covers the word line WL and the sense line SL. A bit line contact plug 31 is connected to the drain region 12d. A bit line 35 is connected to the bit line contact plug 31. The word line WL includes a gate insulation layer 14, a first gate electrode 22, an inter-gate dielectric 24, and a second gate electrode 26. The sense line SL includes a tunnel insulation layer 15, a floating gate electrode 21, an inter-gate dielectric 23, and a control gate electrode 25. The sense line SL is disposed on the active region 12 between the drain region 12d and the floating diffusion region 12f. The word line WL is disposed in the active region 12 between the source region 12s and the floating diffusion region 12f.

As such a semiconductor device becomes more highly integrated, the channel width of the transistor including the word line WL may be reduced. As a result, an amount of a cell current may be reduced and a sense amplifier used to sense an ON/OFF-state of a memory cell may be overloaded. A low power supply voltage arising from the decreased cell current may reduce an operating speed of the semiconductor device.

### SUMMARY OF THE INVENTION

In some embodiments of the present invention, a nonvolatile memory device includes a substrate and a device isolation region disposed in the substrate and abutting a sidewall of an active region defined in the substrate. The device isolation region has a recessed portion. A word line crosses the active region and the recessed portion of the device isolation region and conforms to the sidewall adjacent the recessed portion of the device isolation region. The nonvolatile memory device may further include a sense line crossing the active region and the device isolation region parallel to the word line, the sense line overlying a portion of the device isolation region having a top surface at substantially the same level as a top surface of the active region. An edge of the active region adjacent the sidewall may be rounded.

The word line may include a gate insulation layer on the active region and a gate electrode on the gate insulation layer. A bottom surface of a portion of the gate electrode overlying the active region may be higher than a bottom surface of a portion of the gate electrode overlying the recessed portion of the device isolation region. The gate electrode may conform to the sidewall of the active region.

In further embodiments, the sense line includes a tunnel insulation layer on the active region, a floating gate layer on the tunnel insulation layer, an intergate dielectric layer on the floating gate layer and a control gate electrode on the intergate dielectric layer. A bottom surface of a portion of the floating gate layer overlying the active region may be at substantially the same level as a bottom surface of a portion of the floating gate layer overlying the device isolation region.

Further embodiments of the present invention provide a nonvolatile memory device including a substrate, a device isolation region disposed in the substrate and abutting a sidewall of an active region defined in the substrate, and a word line and a sense line crossing the device isolation region and the active region in parallel. A portion of the device isolation region underlying the wordline is recessed with respect to the active region and the wordline conforms to the sidewall adjacent the recessed portion of the device isolation region. An edge of the active region adjacent the sidewall of the active region may be rounded.

Further embodiments of the present invention provide methods of manufacturing a nonvolatile memory device. A device isolation region is formed in a substrate, the device isolation region abutting a sidewall of an active region defined in the substrate and having a portion recessed with respect to the active region. A word line is formed, the word line crossing the active region and the device isolation region and conforming to the sidewall adjacent the recessed portion of the device isolation region.

Forming a device isolation region may include forming a trench in the substrate adjacent the active region, forming an insulating material layer in the trench and removing a portion of the insulating material layer to expose the sidewall and leave the recessed portion of the device isolation region in the trench. Removing a portion of the insulating material layer to expose the sidewall and leave the recessed portion of the device isolation region in the trench may include wet etching the insulating material layer. The insulating material layer may include a silicon oxide layer, and wet etching the insulating material layer may include wet etching using an etching solution including a hydrofluoric acid (HF).

The methods may further include rounding an edge of the active region adjacent the recessed portion of the device isolation region. Rounding the edge of the active region may include etching the edge with a mixture of NH₄OH, H₂O₂ and H₂O. In further embodiments, rounding the edge of the active region may include oxidizing a portion of the active region at the edge and etching and removing the oxidized portion of the active region.

Forming a word line crossing the active region and the device isolation region and conforming to the sidewall adjacent the recessed portion of the device isolation region may include forming a gate insulation layer on the active region and forming a gate electrode on the gate insulation layer. A bottom surface of a portion of the gate electrode overlying the active region may be higher than a bottom surface of a portion of the gate electrode overlying the recessed portion of the device isolation region.

In further embodiments, the methods include forming a sense line crossing the active region and the device isolation region parallel to the word line. The sense line crosses a portion of the device isolation region having a top surface at substantially the same level as a top surface of the active region. Forming a sense line may include forming a tunnel insulation layer on the active region, forming a floating gate layer on the tunnel insulation layer, forming an intergate dielectric layer on the floating gate layer and forming a control gate electrode on the intergate dielectric layer.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIGS. 1 through 3 are views of a conventional nonvolatile memory device; and

FIGS. 4 through 8 are views illustrating nonvolatile memory device and operations for fabricating the same according to some embodiments of the present invention.

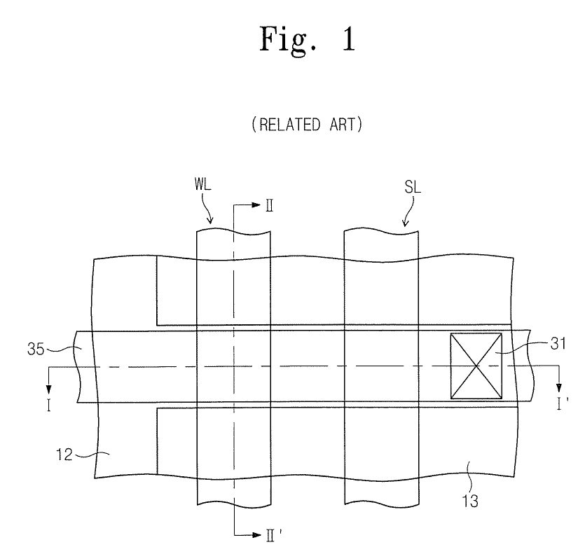

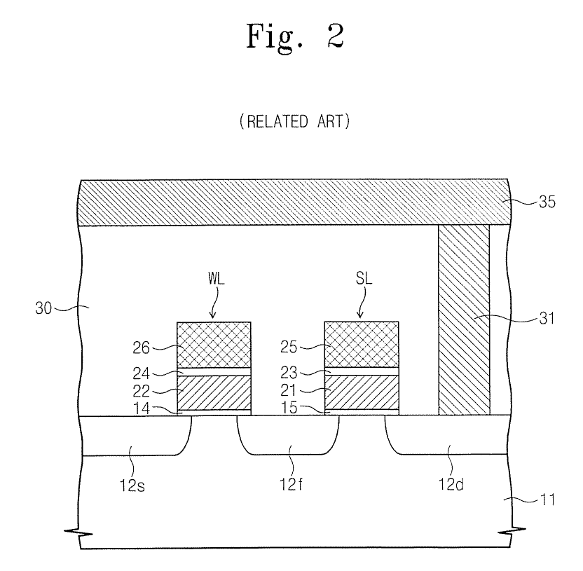

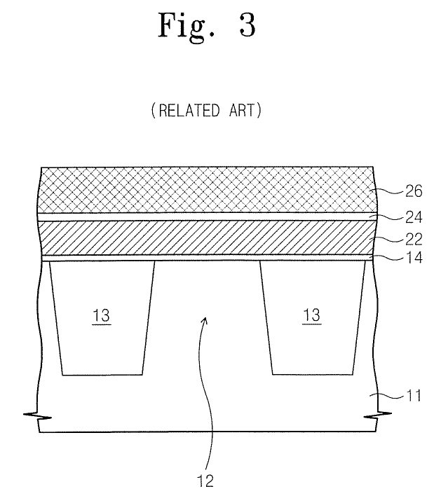

### DETAILED DESCRIPTION OF PREFERRED EMBODIMENTS

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

It will be understood that when an element or layer is referred to as being “on,” “connected to” and/or “coupled to” another element or layer, the element or layer may be directly on, connected and/or coupled to the other element or layer, or intervening elements or layers may be present. In contrast, when an element is referred to as being “directly on,” “directly connected to” and/or “directly coupled to” another element or layer, no intervening elements or layers are present. As used herein, the term “and/or” includes any and all combinations of one or more of the associated listed items.

It will also be understood that, although the terms “first,” “second,” etc., may be used herein to describe various elements, components, regions, layers and/or sections, these elements, components, regions, layers and/or sections should not be limited by these terms. Rather, these terms are used merely as a convenience to distinguish one element, component, region, layer and/or section from another element, component, region, layer and/or section. For example, a first element, component, region, layer and/or section could be termed a second element, component, region, layer and/or section without departing from the teachings of the present invention.

Spatially relative terms, such as “beneath,” “below,” “lower,” “above,” “upper,” “top,” “bottom” and the like, may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, when the device in the figures is turned over, elements described as below and/or beneath other elements or features would then be oriented above the other elements or features. The device may be otherwise oriented (rotated 90 degrees or at other orientations) and the spatially relative descriptors used herein interpreted accordingly. As used herein, “height” refers to a direction that is generally orthogonal to the faces of a substrate.

The terminology used herein is for the purpose of describing particular embodiments only and is not intended to limit the invention. As used herein, the singular terms “a,” “an” and “the” are intended to include the plural forms as well, unless the context clearly indicates otherwise. It will be further understood that the terms “comprise,” “comprising,” “includes,” “including,” “have”, “having” and variants thereof specify the presence of stated features, integers, steps, operations, elements, and/or components, but do not preclude the presence and/or addition of one or more other features, integers, steps, operations, elements, components, and/or groups thereof.

Embodiments of the present invention may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention. Like reference numerals refer to like elements throughout.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of this specification and the relevant art and will not be interpreted in an idealized or overly formal sense unless expressly so defined herein.

In the drawings, the thickness of layers and regions are exaggerated for clarity. It will also be understood that when an element such as a layer, region or substrate is referred to as being “on” or “onto” another element, it may lie directly on the other element or intervening elements or layers may also be present. Like reference numerals refer to like elements throughout the specification.

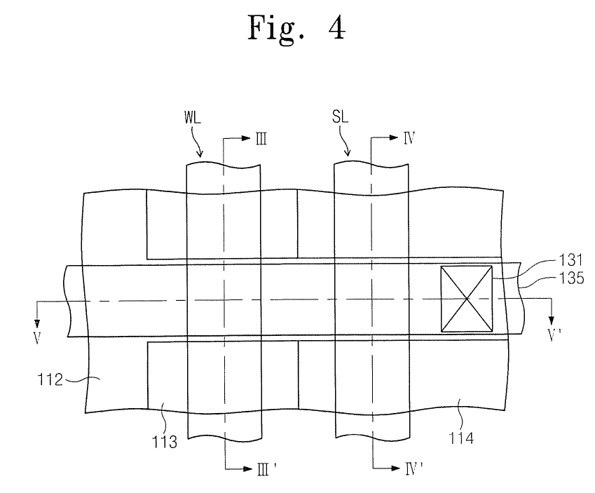

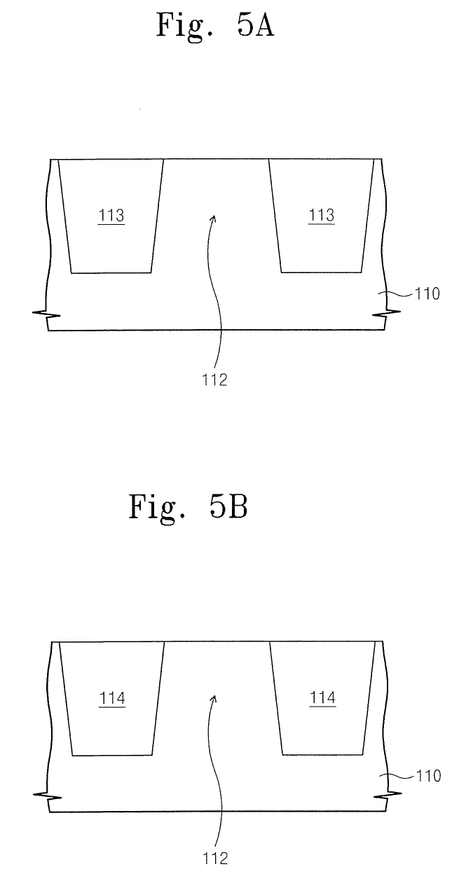

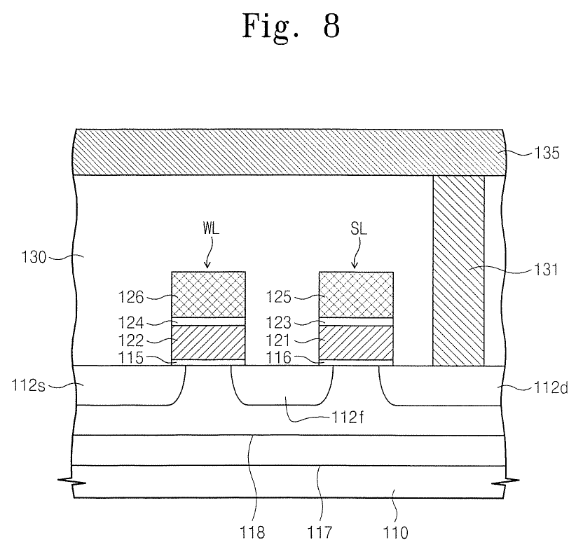

Nonvolatile memory devices and operations for fabricating the same according to some embodiments of the present invention will now be described. FIG. 4 is a plan view illustrating nonvolatile memory devices according to some embodiments of the present invention. FIGS. 5A through 7A are cross-sectional views taken along a line □-□′ of FIG. 4. FIGS. 5B through 7B are cross-sectional views taken along a line □-□′ of FIG. 4. FIG. 8 is a cross-sectional view taken along a line □-□′ of FIG. 4.

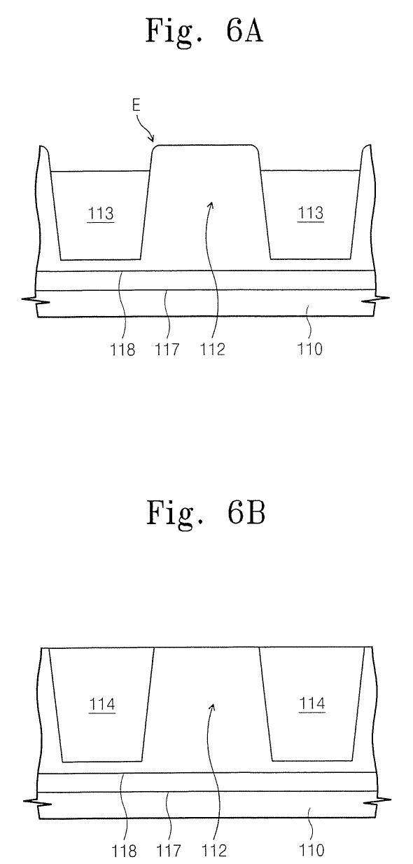

Referring to FIGS. 5A, 5B, 6A and 6B, a semiconductor substrate 110 is prepared. A pocket p-well 118 and an n-well 117 surrounding the pocket p-well 118 may be formed in the semiconductor substrate 110. A first device isolation region 113 and a second isolation region 114 are formed abutting an active region 112 defined in the semiconductor substrate 110. The first device isolation region 113 corresponds to a location for fabrication of a word line WL, and the second device isolation region 114 corresponds to a location for fabrication of a sense line SL. Forming the first device isolation region 113 and the second device isolation region 114 may include forming a trench in the semiconductor substrate 110 and filling the trench with a dielectric material. The first device isolation region 113 and the second device isolation region 114 may be formed using, for example, a shallow trench isolation (STI) process. The first device isolation region 113 and the second device isolation region 114 may include, for example, silicon oxide layers.

Referring to FIG. 6A and 6B, the first device isolation region 113 is recessed to expose a sidewall of the active region 112. As a result, top surface of the active region 112 of the semiconductor substrate 110 protrudes above a top surface of the first device isolation region 113. The top surface of the second device isolation region 114 is at substantially the same level as a top surface of the active region 112 of the semiconductor substrate 110, which can improve a coupling ratio of the nonvolatile memory device.

The first device isolation region 113 may be recessed using, for example, a wet etching process. The wet etching process may be performed, for example, using a solution including hydrofluoric acid (HF). As a result of the etching, an edge E of the protruding semiconductor substrate 110 may be rounded. Rounding the edge E can help reduce concentration of an electric field in this location, which can reduce deterioration of a tunnel isolation region and a gate isolation region of word and sense lines subsequently formed as described below.

Rounding of the edge E of the semiconductor substrate 110 may be achieved by etching the edge E with a mixture of NH₄OH, H₂O₂ and H₂O. Because the edge E tends to etch more intensively than a flat portion of the semiconductor substrate 110, the edge E becomes rounded. In some embodiments, rounding of the edge E of the semiconductor substrate 110 may be achieved by oxidizing the semiconductor substrate near the edge E and etching to remove the oxidized material.

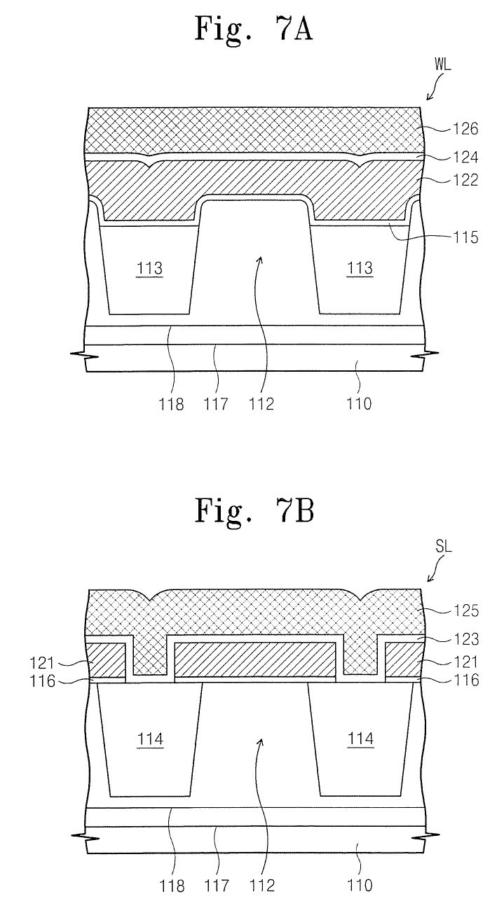

Referring to FIG. 7A and 7B, a word line WL is formed, crossing the active region 112 and the first device isolation region 113. A sense line SL is formed, crossing the active region 112 and the second device isolation region 114. The sense line SL and the word line WL may be patterned at the same time. The sense line SL includes a stacked combination of a tunnel insulation layer 115, a floating gate 121, a first inter-gate dielectric 123, and a control gate 125. The word line WL includes a stacked combination of a gate insulation layer 114, a first gate electrode 122, a second inter-gate dielectric 124, and a second gate electrode 126. The first and the second gate electrodes 126 may be connected through direct contact. Alternatively, the first gate electrode 122 may be connected to a metal contact (not shown).

Referring to FIG. 7A, a bottom surface of a portion of the first gate electrode 122 overlying the protruding portion of the active region 112 is higher than a bottom surface of a portion of the first gate electrode 122 overlying the device isolation region 113. A portion of the first gate electrode 122 may conform to the sidewall of the active region 112 adjacent the device isolation region 113. This structure may provide a substantial widening of the effective channel width, which may thus support increased cell current.

The bottom surface of a portion of the floating gate 121 overlying the active region 112 is at substantially the same level as the bottom surface of a portion of the floating gate 121 overlying the second device isolation region 114. This may improve the coupling ratio of the nonvolatile memory device. Increasing the coupling ratio may increase a voltage transmitted from the control gate 125 to the floating gate 121. A coupling coefficient R may be expressed as follows:

R═Cₒₙₒ/(Cₒₙₒ+Cₜₒ) (1)

where, Cₒₙₒ is capacitance of the gate insulation layer, and Cₜₒ is capacitance of the tunnel insulation layer.

Because the top surface of the second device isolation region 114 is at substantially the same level as the top surface of the active region 112 of the semiconductor substrate 110, an area of the tunnel insulation layer may be reduced, which may reduce the capacitance Cₜₒ of the tunnel insulation layer. Accordingly, the coupling ratio of the nonvolatile memory device may be improved.

Referring to FIGS. 4 and 8, after the word line WL and the sense line SL are formed, an ion-implantation process is performed to form a source region 112s, a drain region 112d, and a floating diffusion region 112f. An interlayer dielectric 130 is formed over the word line WL and the sense line SL. A bit line contact 131 is formed, passing through the interlayer dielectric 130 and contacting the drain region 112d. A bit line 135 is formed in contact with the bit line contact 131.

Referring to FIGS. 7A and 7B, the first device isolation region 113 and the second device isolation region 114 abut the active region 112 defined in the semiconductor substrate 110. A sidewall of the active region 112 is not covered by the first device isolation region 113. The top surface of the first device isolation region 113 is lower than the top surface of the active region 112. The top surface of the second device isolation region 114 is at substantially the same level as the top surface of the active region 112. The first device isolation region 113 and the second device isolation region 114 may include, for example, a silicon oxide layer. A word line WL crosses the active region 112 and the first device isolation region 113 and a sense line SL cross the active region 112 and the second device isolation region 114.

The word line WL includes a gate insulation layer 115, a first gate electrode 122, a first inter-gate dielectric 124, and a second gate electrode 126. A bottom surface of a portion of the first gate electrode 122 overlying the active region 112 is higher than a bottom surface of a portion of the first gate electrode 122 overlying the device isolation region 113. A portion of the first gate electrode 122 conforms to the sidewall of the active region 112. Thus, a substantially expanded effective channel width may be provided without increasing a size of the cell.

The sense line SL includes a tunnel insulation layer 116 on the semiconductor substrate 110, a floating gate 121, a second inter-gate dielectric 123, and a control gate 125. A bottom surface of a portion of the floating gate 121 overlying the active region 112 is at substantially the same level as a bottom surface of the floating gate 121 overlying the second device isolation region 114. As a result, the coupling ratio of the nonvolatile memory device may be improved.

The gate insulation layer 115 and the tunnel insulation layer 116 may include a silicon oxide layer. The first and the second gate electrodes 122 and 126, the floating gate 121, and the control gate 125 may include polysilicon. The first and the second inter-gate dielectrics 124 and 123 may comprise an oxide-nitride-oxide (ONO) layer structure. The edge of the active region 112 of the semiconductor substrate 110 may be rounded where the word line WL crosses the active region 112. The rounded edge may reduce the concentration of an electric field, which can reduce deterioration of the gate insulation layer 115 and the tunnel insulation layer 116.

According to some embodiments of the present invention, the top surface of the first device isolation region crossed by the word line is lower than the top surface of the active region of the semiconductor substrate. Therefore, a substantially greater effective channel width may be achieved to support an increased cell current. A top surface of the second device isolation region crossed by the sense line is at substantially the same level as a top surface of the active region. Therefore, the coupling ratio of the nonvolatile memory device may be improved.

The foregoing is illustrative of the present invention and is not to be construed as limiting thereof. Although a few embodiments of this invention have been described, those skilled in the art will readily appreciate that many modifications are possible in the embodiments without materially departing from the novel teachings and advantages of this invention. Accordingly, all such modifications are intended to be included within the scope of this invention as defined in the claims. The invention is defined by the following claims.

1. A nonvolatile memory device comprising:
a substrate;
a device isolation region disposed in the substrate and abutting a sidewall of an active region defined in the substrate, the device isolation region having a recessed portion; and
a word line crossing the active region and the recessed portion of the device isolation region and conforming to the sidewall adjacent the recessed portion of the device isolation region.

2. The nonvolatile memory device of claim 1, wherein the word line comprises:
a gate insulation layer on the active region; and
a gate electrode on the gate insulation layer.

3. The nonvolatile memory device of claim 2, wherein a bottom surface of a portion of the gate electrode overlying the active region is higher than a bottom surface of a portion of the gate electrode overlying the recessed portion of the device isolation region.

4. The nonvolatile memory device of claim 2, wherein the gate electrode conforms to the sidewall of the active region.

5. The nonvolatile memory device of claim 1 further comprising a sense line crossing the active region and the device isolation region parallel to the word line, the sense line overlying a portion of the device isolation region having a top surface at substantially the same level as a top surface of the active region.

6. The nonvolatile memory device of claim 5, wherein the sense line comprises:
a tunnel insulation layer on the active region;
a floating gate layer on the tunnel insulation layer;
an intergate dielectric layer on the floating gate layer; and
a control gate electrode on the intergate dielectric layer.

7. The nonvolatile memory device of claim 6, wherein a bottom surface of a portion of the floating gate layer overlying the active region is at substantially the same level as a bottom surface of a portion of the floating gate layer overlying the device isolation region.

8. The nonvolatile memory device of claim 1, wherein an edge of the active region adjacent the sidewall is rounded.

9. A nonvolatile memory device comprising:
a substrate;
a device isolation region disposed in the substrate and abutting a sidewall of an active region defined in the substrate;
a word line and a sense line crossing the device isolation region and the active region in parallel,
wherein a portion of the device isolation region underlying the wordline is recessed with respect to the active region and wherein the wordline conforms to the sidewall adjacent the recessed portion of the device isolation region.

10. The nonvolatile memory device of claim 9, wherein an edge of the active region adjacent the sidewall of the active region is rounded.

11.-20. (canceled)
